(19) United States
(12) Patent Application Publication
(10) Pub. No.: US 2025/0162316 A1
(43) Pub. Date: May 22, 2025

(54) LIQUID EJECTING HEAD

(71) Applicant: CANON KABUSHIKI KAISHA, Tokyo (JP)

(72) Inventors: Koji TAKASE, Kanagawa (JP); Takeru YASUDA, Kanagawa (JP); Maki KATO, Tokyo (JP); Shinya IWAHASHI, Kanagawa (JP)

(21) Appl. No.: 18/949,076

(22) Filed: Nov. 15, 2024

(30) Foreign Application Priority Data
Nov. 17, 2023 (JP) 2023-195786

(51) Int. Cl. B41J 2/14; H10N 30/87; H10N 30/88

(52) U.S. Cl. CPC B41J 2/14233; H10N 30/871; H10N 30/877; H10N 30/883; B41J 2002/14241; B41J 2002/14491

(57) ABSTRACT

There is provided a liquid ejecting head capable of suppressing the breakage of a metallic layer connected to a piezoelectric element resulting from a hydrogen ion while suppressing upsizing. The liquid ejecting head has a first substrate provided with a piezoelectric element on one surface, a second substrate provided the one surface of the first substrate and having a space configured so that the piezoelectric element is positioned internally, and a third substrate bonded to the other surface of the first substrate and including a pressure chamber deforming by driving the piezoelectric element and a liquid ejection opening capable of ejecting liquid supplied to the pressure chamber, and in the space, a low-potential electrode which is at a lower potential than one of an electrode in the piezoelectric element is formed on the one surface of the first substrate.

### BACKGROUND OF THE INVENTION

### Field of the Invention

The present invention relates to a liquid ejecting head which is widely applicable to, for example, a printing head capable of ejecting ink by an ink jet system.

### Description of the Related Art

U.S. Pat. No. 9,849,674 discloses a liquid ejecting head formed by adhering a substrate forming an ejection opening, a substrate forming a pressure chamber and a piezoelectric element, and a substrate in which a space covering the piezoelectric element and a flow path are formed by using an adhesive agent.

In the liquid ejecting head disclosed in U.S. Pat. No. 9,849,674, there is a case where the space provided so as to cover the piezoelectric element becomes a high humidity environment because of an effect of water in liquid to be ejected. In a case where the piezoelectric element is driven under the high humidity environment, a hydrogen ion derived from the above water is drawn to a side of one of two electrodes at a low potential because of the electric potential difference occurring between the two electrodes in the piezoelectric element. This may cause a metallic layer of wiring connected to the electrodes of the piezoelectric element or the like to react with the hydrogen ion, dissolve, and break.

Even in a case where the metallic layer is coated with a protective layer, the metallic layer may react with the hydrogen ion in a portion in which the coating ability of the protective layer is low. Incidentally, it can be considered that the enhancement of coating ability by thickening the protective layer improves the breakage of the metallic layer resulting from the hydrogen ion, but in this case, the thickening of the piezoelectric element itself may causes upsizing of a liquid ejection head.

### SUMMARY OF THE INVENTION

The present invention is made in the light of the above problem and provides a liquid ejection head capable of suppressing the breakage of a metallic layer connected to a piezoelectric element resulting from a hydrogen ion while suppressing upsizing of the liquid ejection head.

A liquid ejecting head includes: a first substrate comprising a piezoelectric element on one surface; a second substrate provided the one surface of the first substrate and having a space configured so that the piezoelectric element is positioned internally; and a third substrate provided the other surface of the first substrate and comprising a pressure chamber deforming by driving the piezoelectric element and an ejection opening capable of ejecting liquid supplied to the pressure chamber; wherein in the space, a low-potential electrode which is at a lower potential than a potential of an electrode in the piezoelectric element is formed on the one surface of the first substrate.

The present invention can suppress the breakage of the metallic layer connected to the piezoelectric element resulting from the hydrogen ion while suppressing the upsizing of the liquid ejection head.

Further features of the present invention will become apparent from the following description of exemplary embodiments with reference to the attached drawings.

### BRIEF DESCRIPTION OF THE DRAWINGS

FIG. 1 is a basic schematic configuration diagram of a liquid ejecting head;

FIG. 2 is a schematic configuration diagram of the liquid ejecting head;

FIG. 3 is a plan view of the liquid ejecting head of FIG. 2;

FIG. 4 is a diagram showing a modification of the liquid ejecting head; and

FIG. 5 is a diagram showing a modification of the liquid ejecting head.

### DESCRIPTION OF THE EMBODIMENTS

An example of an embodiment of a liquid ejecting head is explained below with reference to the attached drawings. Incidentally, the following embodiments do not limit the present invention, and not all combinations of features explained in the present embodiment are essential for solving means of the present invention. Further, the positions and shapes of constituent elements described in the embodiments are only examples, and the present invention is not intended to be limited to these.

### Basic Schematic Configuration of Liquid Ejecting Head

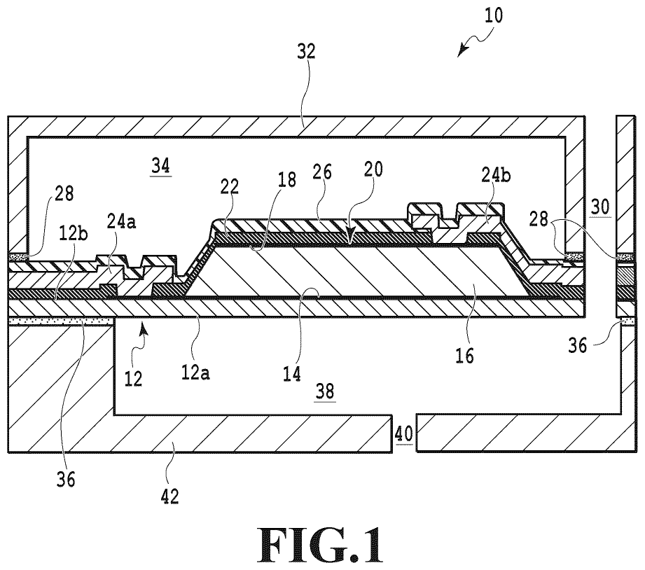

FIG. 1 is a cross-sectional view showing a basic schematic configuration of a liquid ejecting head. A liquid ejecting head 10 of FIG. 1 is formed by bonding a first substrate 12, a second substrate 32, and a third substrate 42. In the present embodiment, a diffusion prevention layer (not illustrated) formed of TiO or the like and a contact layer (not illustrated) formed of Ti or the like may be formed on one surface 12a and the other surface 12b of the first substrate 12. A first electrode layer 14 formed of Pt or the like is provided in the one surface 12a of the first substrate 12, and a piezoelectric layer 16 is provided on the first electrode layer 14. In the present embodiment, the piezoelectric layer 16 is formed of PZT or the like. A second electrode layer 18 formed of TiW or the like is provided on the piezoelectric layer 16. Thereby, in the liquid ejecting head 10, a piezoelectric element 20 is formed on the one surface 12a of the first substrate 12 by the first electrode layer 14, the piezoelectric layer 16, and the second electrode layer 18.

An insulation layer 22 formed of SiO or the like is formed on the piezoelectric element 20 formed by the first electrode layer 14, the piezoelectric layer 16, and the second electrode layer 18. A metallic wiring layer 24 (24a and 24b) formed of Al, AlSi, AlCu or the like is provided on the insulation layer 22. The insulation layer 22 has an opening on part of the first electrode layer 14, and the metallic wiring layer 24a is connected to the first electrode layer 14 in the opening portion. Thus, the metallic wiring layers 24a and 24b function as connection wiring connecting to an electrode of the piezoelectric element 20 in the present embodiment.

Further, the insulation layer 22 has an opening on part of the second electrode layer 18, and the metallic wiring layer 24b is connected to the second electrode layer 18 in the opening portion. Incidentally, a barrier layer (not illustrated) made of Ti or TiN may be formed between the first electrode layer 14 and the metallic wiring layer 24a. Similarly, the barrier layer (not illustrated) made of Ti or TiN may be formed between the second electrode layer 18 and the metallic wiring layer 24b.

Further, a first protective layer 26 which is formed of SiO, SiN, SiC or the like so as to cover the insulation layer 22 and the metallic wiring layer 24 is provided in the liquid ejecting head 10. A second substrate 32 forming a space 34 covering a flow path 30 and the piezoelectric element 20 is bonded to the first protective layer 26 via a first adhesive layer 28. Furthermore, a third substrate 42 which forms a pressure chamber 38 together with the other surface 12b and in which an ejection opening 40 which can eject liquid accumulated in the pressure chamber 38 is formed is bonded to the other surface 12b of the first substrate 12 though a second adhesive layer in the liquid ejecting head 10.

In the liquid ejecting head 10 formed in this manner, the piezoelectric layer 16 is deformed by applying an electric voltage to the piezoelectric element 20 through the metallic wiring layer 24, and thereby the pressure chamber 38 is deformed. In this case, the liquid supplied from the flow path 30 and accumulated in the pressure chamber 38 is ejected from the ejection opening 40 because of pressure change caused by the deformation of the pressure chamber 38. Incidentally, in the liquid ejecting head 10, a plurality of the piezoelectric elements 20 are arranged in a direction (a direction orthogonal to a paper face of FIG. 1) intersecting a bonding direction (a vertical direction of FIG. 1) of a substrate, and the pressure chamber 38 and the ejection opening 40 or the like are formed in a position corresponding to the piezoelectric element 20. The bonding direction (providing direction) of the substrate means a bonding direction of the second substrate 32 and the third substrate 42 with respect to the first substrate 12.

### Regarding Breakage of the Metallic Wiring Layer 24

Here, a process of the occurrence of breakage of the metallic wiring layer 24 in a case where the piezoelectric element 20 is driven is explained. Incidentally, in the following explanations, a voltage of 0V and a voltage of 40V are applied to the first electrode layer 14 and the second electrode layer 18, respectively in order that the electric potential difference between the first electrode layer 14 and the second electrode layer 18 is at a voltage of 40V in the piezoelectric element 20.

The first adhesive layer 28 is exposed in the flow path 30 in the liquid ejecting head 10. Therefore, water contained in the liquid supplied to the pressure chamber 38 via the flow path 30 penetrates through the space 34 via the first adhesive layer 28, and thereby the space 34 becomes a high humidity environment. In a case where the piezoelectric element 20 is driven, the occurrence of the electric potential difference between the first electrode layer 14 and the second electrode layer 18 causes a hydrogen ion (derived from the water penetrating through the adhesive layer 28) existing in the space 34 to be drawn to a side of the first electrode layer 14 and the metallic wiring layer 24a which is at a relatively low potential. The hydrogen ion drawn in this way penetrates through a portion of the first protective layer 26 having low coating ability and reaches the metallic wiring layer 24a connected to the first electrode layer 14. This causes metal such as Al, AlSi, and AlCu constituting the metallic wiring layer 24a to react with the hydrogen ion and to dissolve, and the metallic wiring layer 24a breaks. Incidentally, in the present specification, the breakage of the metallic wiring layer 24a includes loss and degradation of a function of the metallic wiring layer 24a and a change in outer appearance including the first protective layer 26 (outer appearance abnormality).

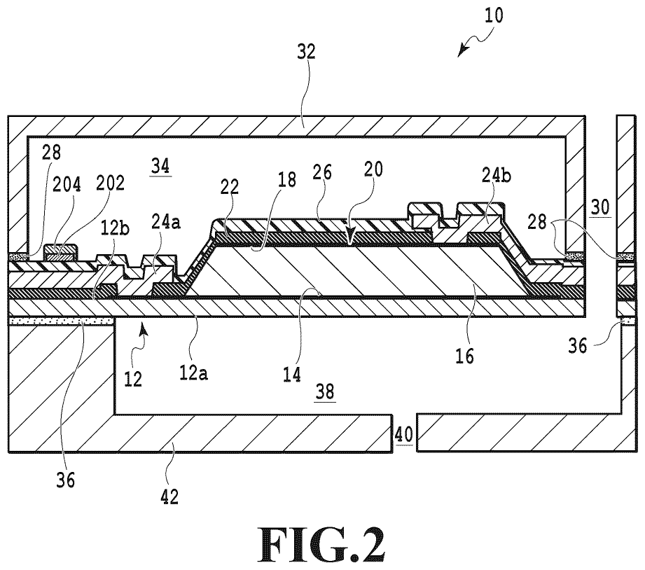

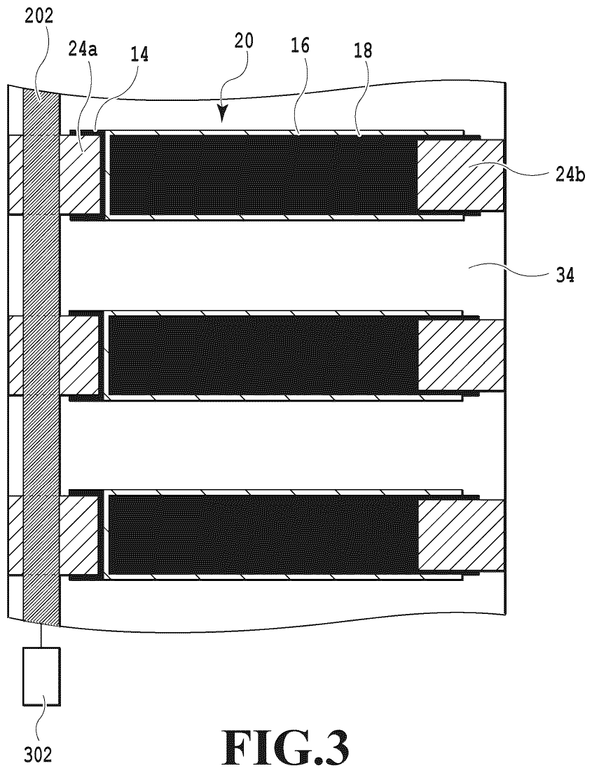

Then, in the present embodiment, the third electrode layer to which a voltage which is lower than one applied to the first electrode layer 14 is applied is provided in the space 34 in order to suppress the occurrence of the breakage of the metallic wiring layer 24a. An explanation about the third electrode layer provided in the liquid ejecting head 10 of the present embodiment is given below with reference to FIGS. 2 and 3. FIG. 2 is a diagram showing the third electrode layer provided in the liquid ejecting head 10. FIG. 3 is a diagram of the inside of the space 34 of the liquid ejecting head 10 of FIG. 2 viewed from one side in the bonding direction of the substrate. Incidentally, in FIG. 3, part of a configuration such as the first protective layer 26 and a second protective layer 204 (discussed later) is omitted for an easy understanding.

In the space 34, the third electrode layer 202 is formed near a connecting portion of the first electrode layer 14 and the metallic wiring layer 24a without contacting the piezoelectric element 20. In the present embodiment, the third electrode layer 202 is an upper layer above the metallic wiring layer 24a and is formed in a position where the third electrode layer 202 does not overlap the first electrode layer 14 or the second electrode layer 18, that is, the piezoelectric element 20 as viewed from the bonding direction of the substrate (the vertical direction of FIG. 2). Further, in the present embodiment, the third electrode layer 202 extends in an array direction of the piezoelectric element 20 (a vertical direction of FIG. 3) intersecting the bonding direction (the vertical direction of FIG. 2) so as to overlap respective metallic wiring layers 24a connected to the plurality of the piezoelectric elements 20 as viewed from the bonding direction. The third electrode layer 202 is coated with the second protective layer 204 formed of SiO, SiN, SiC, for example. In other words, the third electrode layer 202 is coated with a protection film. It is preferable that the third electrode layer 202 be formed of noble metal, such as Pt, Ru, or the like.

In a case where the piezoelectric element 20 is driven, a voltage which is lower than one applied to the first electric layer 14, for example, a voltage of −10V is applied to the third electric layer 202 from an external power source 302 (see FIG. 3). In other words, the third electrode layer 202 is at a negative electric potential with respect to a potential of the first substrate 12. This causes the hydrogen ion to be drawn to the third electrode layer 202 which is at the lowest potential of the first electrode layer 14 (and the metallic wiring layer 24a), the second electrode layer 18 (and the metallic wiring layer 24b), and the third electrode layer 202 which are positioned in the space 34. Therefore, the amount of hydrogen ions drawn to the first electrode layer 14 and the metallic wiring layer 24a is reduced, and the occurrence of the breakage of the metallic wiring layer 24a resulting from the hydrogen ion is suppressed. Thus, in the present embodiment, the third electrode layer 202 functions as a low potential electrode which is at a lower potential than that of the first electrode layer 14 and the second electrode layer 18 of the piezoelectric element 20.

The third electrode layer 202 can draw more hydrogen ions by enlarging a surface area facing the space 34 via the second protective layer 204. Further, the third electrode layer 202 is excellently coated with the second protective layer 204 by providing the third electrode layer 202 in a region whose film thickness is small and whose background is flat, and the breakage of the third electrode layer 202 becomes less likely to occur.

### Operational Effect

As described earlier, in the liquid ejecting head 10, the third electrode layer 202 to which the voltage which is lower than the voltage applied to the first electrode layer 14 is applied is provided near the connecting portion of the first electrode layer 14 and the metallic wiring layer 24a on a low potential side of the two electrode layers forming the piezoelectric element 20. Thus, the hydrogen ion in the space 34 is drawn to the third electrode layer 202 not electrically connected to the piezoelectric element 20, and the breakage of the metallic wiring layer 24a resulting from the hydrogen ion becomes less likely to occur.

In addition, the coating ability of the second protective layer 204 is enhanced by making the film thickness of the third electrode layer 202 small and providing the third electrode 202 in a region whose background is flat, and an attempt to make the third electrode layer 202 to last longer can be made. Further, thickening of the liquid ejection head 10 in the bonding direction of the substrate can be suppressed by reducing the film thickness of the third electrode layer 202, and the upsizing in the bonding direction can be suppressed.

### Other Embodiments

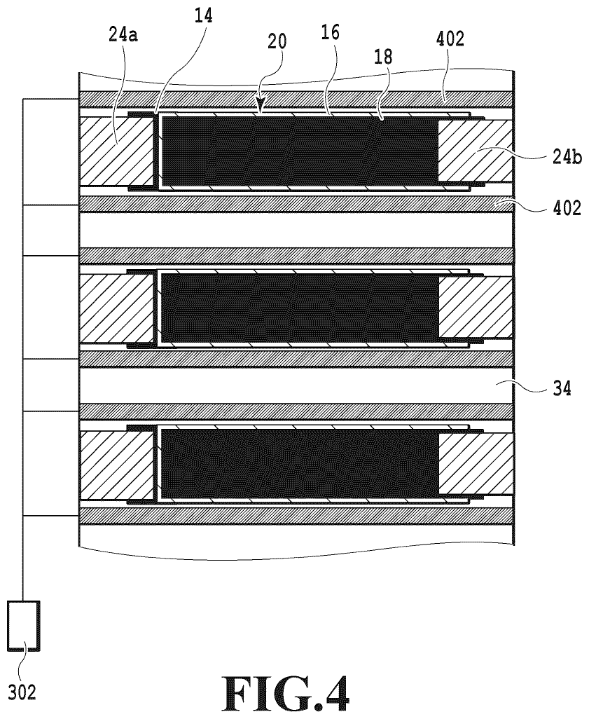

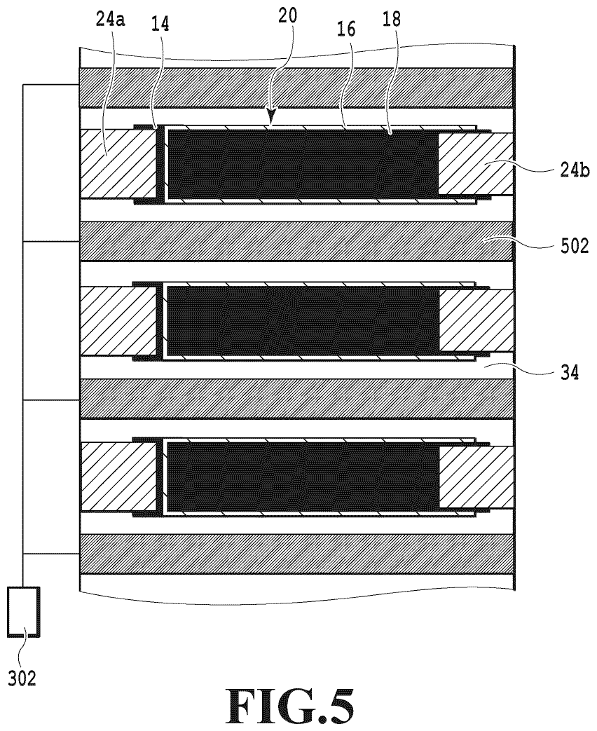

Incidentally, the above embodiment may be deformed as shown in (1) to (3) below.
(1) As in the above embodiment, the number of pieces of wiring which is drawn from the third electrode layer 202 can be reduced by arranging the third electrode layer 202 on the plurality of the metallic wiring layers 24a via the first protective layer 26. Further, an interval between adjacent piezoelectric elements 20 can be short. Thus, the formation of such a configuration contributes to the downsizing of the liquid ejecting head 10. However, the arrangement position of the third electrode layer 202 is not limited to this, and the third electrode layer 202 may extend in parallel in an extending direction of each piezoelectric element 20 as shown in FIGS. 4 and 5, for example.

FIGS. 4 and 5 are diagrams showing modifications of the arrangement positions of the third electrode layer 202. Incidentally, in FIGS. 4 and 5, part of configurations such as the first protective layer 26 and the second protective layer with which the third electrode layer is coated are omitted as in FIG. 3. In FIG. 4, for example, a third electrode layer 402 is provided on both sides in the array direction of each piezoelectric element 20 (a vertical direction of FIG. 4) along the extending direction of the piezoelectric element 20. The third electrode 402 may be provided on only one side in the array direction of each piezoelectric element 20.

Further, in FIG. 5, a third electrode layer 502 is provided between the adjacent piezoelectric elements 20 along the extending direction of the piezoelectric element 20. Incidentally, in this case, for example, the third electrode layer 502 may be provided on the outside of the piezoelectric elements 20 on both sides in the array direction. In a case where the third electrode layer 502 is provided, the number of pieces of wiring drawn from the third electrode layer 502 can be reduced as compared with a case where the third electrode layer 402 is provided.

In addition, an illustration is omitted, but the formation of the third electrode layers 402 and 502 is not limited to forming the third electrode layers 402 and 502 longer than the piezoelectric element 20 in the extending direction of the piezoelectric element 20. The length in the above extending direction of the third electrode layers 402 and 502 may be shorter than the length in the above extending direction of the piezoelectric element 20. In this case, for example, the third electrode layers 402 and 502 are arranged near the connecting portion of the first electrode layer 14 and the metallic wiring layer 24a.
(2) In the above embodiment, the voltage is applied in such a way that the first electrode layer 14 is at a low potential and the second electrode layer 18 is at a high potential, but the application of a voltage is not limited to this. The first electrode layer 14 may be at a high potential and the second electrode layer 18 may be at a low potential. Incidentally, in this case, the third electrode layer 202 is arranged in a position near the connecting portion of the second electrode layer 18 and the metallic wiring layer 24b and a position where the third electrode layer 202 does not overlap the first electrode layer 14 or the second electrode layer 18 as viewed from the bonding direction.
(3) The above embodiment and the respective embodiments indicated in (1) and (2) above may be combined as appropriate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-195786, filed Nov. 17, 2023, which is hereby incorporated by reference wherein in its entirety.

What is claimed is:

1. A liquid ejecting head comprising:
a first substrate comprising a piezoelectric element on one surface;
a second substrate provided the one surface of the first substrate and having a space configured so that the piezoelectric element is positioned internally; and
a third substrate provided the other surface of the first substrate and comprising a pressure chamber deforming by driving the piezoelectric element and an ejection opening capable of ejecting liquid supplied to the pressure chamber;
wherein in the space, a low-potential electrode which is at a lower potential than a potential of an electrode in the piezoelectric element is formed on the one surface of the first substrate.

2. The liquid ejecting head according to claim 1, wherein
a plurality of the piezoelectric elements are arranged in a direction intersecting a providing direction of the second substrate and the third substrate with respect to the first substrate,
wherein the low-potential electrode extends in an array direction of the piezoelectric element.

3. The liquid ejecting head according to claim 2, wherein
the low-potential electrode does not overlap the piezoelectric element as viewed from the providing direction but overlaps connection wiring connected to an electrode on a low-potential side in the piezoelectric element.

4. The liquid ejecting head according to claim 1, wherein
a plurality of the piezoelectric elements are arranged in a direction intersecting a providing direction of the second substrate and the third substrate with respect to the first substrate,
wherein the low-potential electrode extends in a direction intersecting an array direction and the providing direction of the piezoelectric element.

5. The liquid ejecting head according to claim 4, wherein
the low-potential electrode is provided to each piezoelectric element on both sides in the array direction.

6. The liquid ejecting head according to claim 4, wherein
the low-potential electrode is provided between the piezoelectric elements which are adjacent to each other.

7. The liquid ejecting head according to claim 1, wherein
the low-potential electrode is formed of noble metal.

8. The liquid ejecting head according to claim 1, wherein
the low-potential electrode is at a negative electric potential with respect to a potential of the first substrate.

9. The liquid ejecting head according to claim 1, wherein
the low-potential electrode is covered with a protective layer.
